(19) United States
(12) Patent Application Publication
(10) Pub. No.: US 2007/0045635 A1
(43) Pub. Date: Mar. 1, 2007

(54) Light emitting diode device

(75) Inventor: Ga-Lane Chen, Fremont, CA (US)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Chen City (TW)

(21) Appl. No.: 11/416,368

(22) Filed: May 1, 2006

(30) Foreign Application Priority Data
Aug. 26, 2005 (CN) 200510036920.X

(51) Int. Cl. H01L 33/00

(52) U.S. Cl. 257/79

(57) ABSTRACT

A light emitting diode device includes a substrate, a reflective layer, a joint layer and a light emitting diode layer stacked in turn from bottom to top, a material of the main substrate being Cu or Al, and a material of the reflective layer being metal Al or Ag, or alloy AlX or AgY, X represents Cu, Mg or Au, Y represents Cu, Au or Al. A method for manufacturing the light emitting diode device is also provided.

### CROSS REFERENCE

This application relates to a contemporaneously filed application having the same title, the same applicant and the same assignee with the instant application.

### TECHNICAL FIELD

The present invention relates to a light source, in particular, to a light emitting diode device and a method for manufacturing the same.

### BACKGROUND

Light emitting diodes (LED) is a solid semiconductor element, which can be used in a wide variety of devices, for example, optical displays, traffic lights, data storage devices, communication devices, illumination devices, and medical devices.

It is known to all that, when an electric power having only 2˜3 volt is introduced to an LED, two separate carriers—electrons with negative electric charge and holes with positive electrical charge—are produced. When the two carriers recombine with each other, extra energy is produced and then release at a photon shape, thus the LED illuminates. For different materials used therein, energy levels of electrons and holes are different, which can affect extra energy and wavelength of light produced during the recombination of the electrons and holes, thus different colors of red, green, blue etc are displayed.

In a light emitting diode device, there is a transparent substrate and an LED stack attached thereto. Most of the transparent substrates are made from III-V group compound semiconductor materials in Periodic Table of Elements. III-V group compound semiconductor materials are combination of group-III element, i.e., boron (B), aluminum (Al), gallium (Ga), indium (In) or thallium (Ta), and group-V element, i.e., nitrogen (N), phosphorus (P), arsenic (As), antimony (Ti) or bismuth (Bi), such as GaAs, InP, GaN or GaAsP etc.

Those III-V group compound semiconductor materials have properties of high frequency, radiation resistant and high insulated, and are widely used in LED field. However, they also have disadvantages of energy absorption and low heat transmission. Firstly, since light emitted by LED has isotropy property, part of it will emit to the transparent substrate made from those materials, and then be absorbed by the substrate. Thus light energy is lost, and luminance of LED device will decrease. Secondly, due to low heat transmission of transparent substrate, heat produced by LED will not be dispersed efficiently, thus LED of those kind can only be used as component with low power, which restrict further application of LED.

Therefore, a heretofore-unaddressed need exists in the industry to address the aforementioned deficiencies and inadequacies.

### SUMMARY

In a preferred embodiment, a light emitting diode device is provided, which includes a substrate, a reflective layer, a joint layer and a light emitting diode layer stacked in turn from bottom to top. A material of the main substrate is Cu or Al, and a material of the reflective layer is metal Al or Ag, or alloy AlX or AgY, X represents Cu, Mg or Au, Y represents Cu, Au or Al.

In a second preferred embodiment, a method for manufacturing the light emitting diode device is also provided, which includes the following steps: providing a assist substrate and a substrate; forming a light emitting diode layer on the assist substrate; forming a reflective layer on the main substrate; forming a joint layer on the reflective layer; joining the reflective layer and the light emitting diode layer together via the joint layer; and removing the assist substrate.

### BRIEF DESCRIPTION OF THE DRAWINGS

Many aspects of the present light emitting diode device and method for manufacturing the same can be better understood with reference to the following drawings. The components in the drawings are not necessarily to scale, emphasis instead being placed upon clearly illustrating the principles of the present light emitting diode device and method for manufacturing the same. Moreover, in the drawings, like reference numerals designate corresponding parts throughout the several views.

FIG. 1 is a schematic view of a structure of a light emitting diode device of the preferred embodiment.

FIG. 2A˜FIG. 2E schematically illustrating a method for manufacturing the same light emitting diode device of the preferred embodiment.

FIG. 3 is a schematic view showing illuminate principle of the light emitting diode device of the preferred embodiment.

FIG. 4 is a schematic view showing heat dissipation principle of the light emitting diode device of the preferred embodiment.

### DETAILED DESCRIPTION

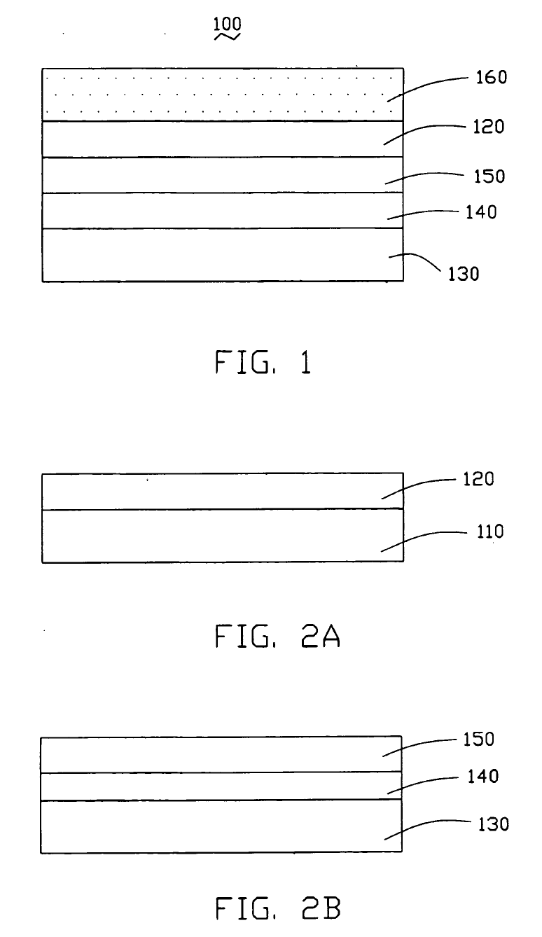

Referring to FIG. 1, a light emitting diode (LED) device 100 includes a main substrate 130, a reflective layer 140, a joint layer 150, an LED layer 120 and a diffusing layer 160 stacked in turn from bottom to top.

A material of the main substrate 130 is copper or aluminum, with surface roughness of 0.2˜0.8 nanometers. A material of the reflective layer 140 is metal Al or Ag, or alloy AlX or AgY, wherein X represents Cu, Mg or Au, Y represents Cu, Au or Al. Content of X or Y in the alloys is under 10 percents. A thickness of the reflective layer 140 is in the range of 10˜200 nanometers, preferable 20˜50 nanometer. Reflectivity of the reflective layer 140 is above 92 percent.

A material of the joint layer 150 is Au, Al or Ag, with a thickness of 5˜20 nanometer. The diffusing layer 160 has a thickness in the range of 100˜500 nanometers. A material of the diffusing layer 160 is mainly SiO₂, blended with nano particles such as Al₂O₃, SiOₓ or TiOₓ, wherein x is in the range of 1˜2. The blended nano particles have an average grain size in the range of 2˜20 nanometers, preferable 5˜10 nanometers.

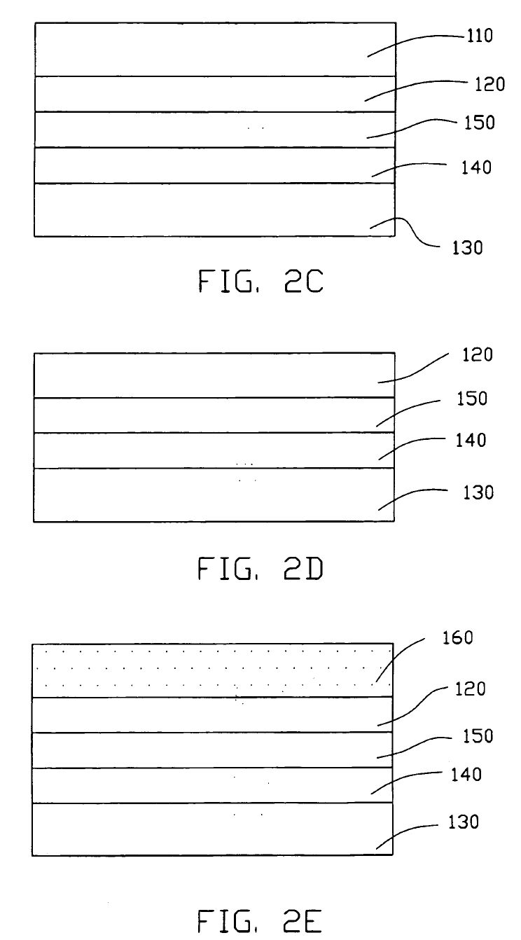

FIGS. 2A-2E illustrate a method for manufacturing the LED device 100. Referring to FIG. 2A, an assist substrate 110 made from a material of GaAs is provided. Other III-V group compound semiconductor materials such as GaAsP, AlGaAs etc can also be suitable. Then, an LED layer 120 is deposited on the assist substrate 110 uniformly by spin coating, uniform coating, pre-coating or chemical vapor depositing method.

Referring to FIG. 2B, a main substrate 130 made from a material of Cu or Al is provided. A surface of the main substrate 130 has a surface roughness of 0.2˜0.8 nanometers. A reflective layer 140 is deposited on the main substrate 130. A material of the reflective layer 140 is metal Al or Ag, or alloy AlX or AgY, wherein X represents Cu, Mg or Au, Y represents Cu, Au or Al. Content of X or Y in the alloys is under 10 percents. Reflectivity of the reflective layer 140 is above 92 percent. The reflective layer 140 has a thickness in the range of 10˜200 nanometers, preferable 20˜50 nanometers. The reflective layer 140 is deposited on the main substrate 130 by reactive direct current sputtering or reactive frequency sputtering method.

A joint layer 150 is deposited on the reflective layer 140 by reactive direct current sputtering or reactive frequency sputtering method. A material of the joint layer 150 is metal conductor, such as Au, Al or Ag. The joint layer 150 has a thickness in the range of 5˜20 nanometers.

Referring to FIG. 2C, the assist substrate 110 and the LED layer 120 is turned over to make the LED layer 120 cover the joint layer 150, and the LED layer 120 is joined with the reflective layer 140 via the joint layer 150, at a joining temperature of 200˜400 degrees centigrade.

Referring to FIG. 2D, the assist substrate 110 is removed by chemical etching, chemical mechanical polishing, sputter etching or plasma etching method. Thereby the LED 100 is formed with the main substrate 130, the reflective layer 140, the joint layer 150 and the LED layer 120 stacked in turn from bottom to top.

Referring to FIG. 2E, a diffusing layer 160 can be further deposited on the LED layer 120 with a thickness of 100˜500 nanometer. A material of the diffusing layer 160 is transparent silicon dioxide, blended with nano particles such as Al₂O₃, SiOₓ or TiOₓ, wherein x is in the range of 1˜2. The nano particles have an average grain size in the range of 2˜20 nanometers, preferable 5˜10 nanometers. The diffusing layer 160 is configured for scattering light entered thereinto to a wide light distribution angle via multi-scattering. For the LED device 100, the diffusing layer 160 is a light emitting surface, thus a wide light distribution angle is obtained.

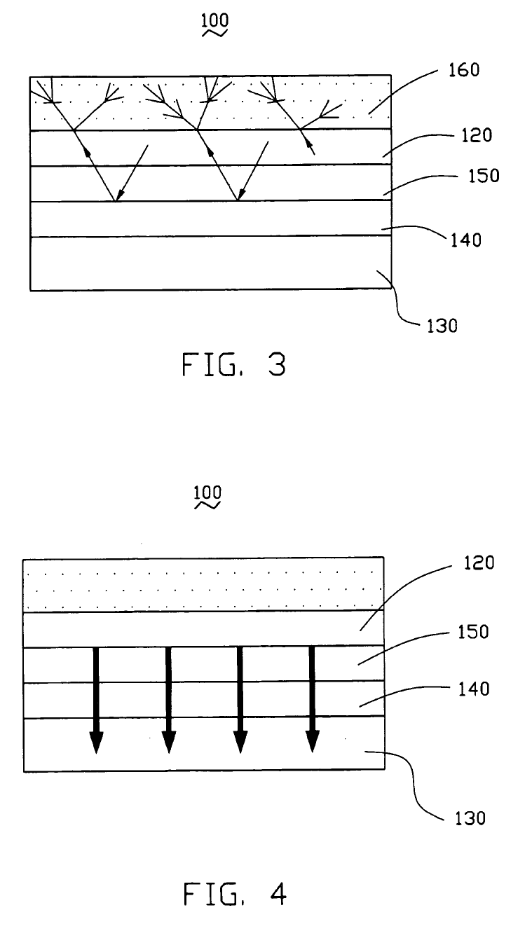

Referring to FIG. 3, it shows illumination principle of the LED device 100. Arrows shown in FIG. 3 represent light transmission direction. Light emitted from the LED layer 120 has isotropy property A part of light beams enter into the diffusing layer 160 directly, and are scattered by the nano particles in the diffusing layer 160. Then the light beams change their original directions and diffuse to all directions, thus obtain a wide light distribution angle. Other light beams reach the reflective layer 140 and are reflected back into the diffusing layer 160 directly by the reflective layer 140, thus usage efficiency of the light beams provided by the light emitting diode device 100 is improved, and illumination thereof is enhanced.

Referring to FIG. 4, it shows heat dissipation principle of the LED device 100. Arrows in FIG. 4 represent heat dissipation direction. First of all, since materials of the joint layer 150 and the reflective layer 140 are made from metal materials, both two layers have good heat dissipation property Thus heat produced by the LED layer 120 can be conducted to the main substrate 130 rapidly via the joint layer 150 and the reflective layer 140. Secondly, since the main substrate 130 is made of materials of good heat conductor, which could be functioned as a heat sink to lead heat out of the device.

The LED device 100 could be used in all kind of display products, consumer electronic products, communication electronic products and car electronic products.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A light emitting diode device comprising a substrate, a reflective layer, a joint layer and a light emitting diode layer stacked in turn from bottom to top, a material of the main substrate being Cu or Al, and a material of the reflective layer being metal Al or Ag, or alloy AlX or AgY, X represents Cu, Mg or Au, Y represents Cu, Au or Al.

2. The light emitting diode device as claimed in claim 1, wherein a content of X or Y in the alloys is under 10 percent.

3. The light emitting diode device as claimed in claim 1, wherein a thickness of the reflective layer is in the range from 10 to 200 nanometers.

4. The light emitting diode device as claimed in claim 1, wherein a reflectivity of the reflective layer is above 92 percent.

5. The light emitting diode device as claimed in claim 1, wherein a material of the joint layer is Au, Al or Ag.

6. The light emitting diode device as claimed in claim 1, wherein a thickness of the joint layer is in the range from 5 to 20 nanometers.

7. The light emitting diode device as claimed in claim 1, further comprising a diffusing layer on a side of the light emitting diode layer opposite to the joint layer.

8. The light emitting diode device as claimed in claim 7, wherein the diffusing layer is mainly made from silicon dioxide with nano particles mixed therein, the nano particles are Al₂O₃, SiOₓ or TiOₓ, where x is in the range from 1 to 2.

9. The light emitting diode device as claimed in claim 8, wherein the nano particles have an average grain size in the range from 2 to 20 nanometers.

10. The light emitting diode device as claimed in claim 7, wherein a thickness of the diffusing layer is in the range from 100 to 500 nanometers.

11. A method for manufacturing light emitting diode device comprising the following steps:
providing an assist substrate and a main substrate, a material of the main substrate being metal Cu or Al;
forming a light emitting diode layer on the assist substrate;
forming a reflective layer on the main substrate, a material of which being metal Al or Ag, or alloy AlX or AgY, X represents Cu, Mg or Au, Y represents Cu, Au or Al;
forming a joint layer on the reflective layer;
joining the reflective layer and the light emitting diode layer together via the joint layer, and
removing the assist substrate.

12. The method for manufacturing light emitting diode device as claimed in claim 11, wherein a material of the assist substrate is III-V group compound semiconductor.

13. The method for manufacturing light emitting diode device as claimed in claim 11, wherein the light emitting diode layer is formed by depositing, spin sputtering, uniform coating, pre-coating or chemical vapor depositing method.

14. The method for manufacturing light emitting diode device as claimed in claim 11, wherein the reflective layer and the joint layer are formed by reactive direct current sputtering or reactive frequency sputtering method.

15. The method for manufacturing light emitting diode device as claimed in claim 11, wherein a temperature of the joining step is in the range from 200 to 400 degrees centigrade.

16. The method for manufacturing light emitting diode device as claimed in claim 11, wherein the removing assist substrate step is performed by chemical etching, chemical mechanical polishing, sputter etching or plasma etching method.

17. The method for manufacturing light emitting diode device as claimed in claim 11, further comprising a step of forming a diffusing layer on the light emitting diode layer after removing the assist substrate.

18. The method for manufacturing light emitting diode device as claimed in claim 17, wherein the diffusing layer is formed by co-sputtering nano particles and silicon dioxide.
